(19) United States
(12) Patent Application Publication
(10) Pub. No.: US 2012/0222736 A1
(43) Pub. Date: Sep. 6, 2012

(54) FRONT CONTACT SOLAR CELL MANUFACTURE USING METAL PASTE METALLIZATION

(75) Inventors: James M. Gee, Albuquerque, NM (US); Charles F. Gay, Westlake Village, CA (US)

(73) Assignee: APPLIED MATERIALS, INC., Santa Clara, CA (US)

(21) Appl. No.: 13/040,946

(22) Filed: Mar. 4, 2011

(51) Int. Cl. H01L 31/0224

(52) U.S. Cl. 136/256; 438/98; 257/E31.124

(57) ABSTRACT

Embodiments of the invention contemplate the formation of a high efficiency solar cell using novel methods to form metal contact structures of the solar cell device. In one embodiment, a solar cell device includes a substrate comprising a doped semiconductor material, a surface formed on the substrate having a second doped semiconductor layer having a conductivity type opposite to the first doped semiconductor material, a dielectric layer disposed on the surface of the substrate, a metal contact structure formed in the dielectric layer with a first predetermined cross sectional area, and a metal line formed on the metal contact structure with a second predetermined cross sectional area, wherein the second predetermined cross sectional area is larger than the first predetermined cross sectional area.

### BACKGROUND OF THE INVENTION

1. Field of the Invention

Embodiments of the invention generally relate to the fabrication of photovoltaic cells.

2. Description of the Related Art

Solar cells are photovoltaic devices that convert sunlight directly into electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost to form solar cells.

Conventional silicon solar cells, such as crystalline-silicon solar cells, use a metal based contact structure for the front-surface current collection and for the rear surface contacting areas. The metal contact structures in connection with the substrate create an ohmic contact. Contact resistivity between the metal contact structures and the substrate is always desired to be low so as to maintain good electrical performance of the solar cell devices. Low charge recombination loss is also desired at the interface of the metal contacts and the substrate so as to keep high conversion efficiency of the solar cells.

Therefore, there exists a need for improved methods to form the metal contact structures formed on a surface of a substrate to form a solar cell with desired electric performances.

### SUMMARY OF THE INVENTION

Embodiments of the invention contemplate the formation of a high efficiency solar cell using novel methods to form metal contact structures of the solar cell device. In one embodiment, a solar cell device includes a substrate comprising a doped semiconductor material, a surface formed on the substrate having a second doped semiconductor layer having a conductivity type opposite to the first doped semiconductor material, a dielectric layer disposed on the surface of the substrate, a metal contact structure formed in the dielectric layer with a first predetermined cross sectional area, and a metal line formed on the metal contact structure with a second predetermined cross sectional area, wherein the second predetermined cross sectional area is larger than the first predetermined cross sectional area.

In another embodiment, a method for manufacturing metal contact structures for a solar cell device includes providing a substrate having a dielectric layer disposed thereon, selectively disposing contact metal paste on the dielectric layer, firing the contact metal paste disposed on the dielectric layer to etch through the dielectric layer, forming contact openings in the dielectric layer, forming metal contact structures in the contact opening formed in the dielectric layer etched through the contact metal paste during the firing process, and selectively disposing a metal line over the contact structures formed in the dielectric layer.

In yet another embodiment, a method for manufacturing metal contact structures for a solar cell device includes providing a substrate having a dielectric layer disposed thereon, performing a contact opening process in the dielectric layer to selectively form a plurality of contact openings in the dielectric layer, disposing metal contacts in the contact openings formed in the dielectric layer, wherein the metal contacts include a top portion connecting to a low portion, wherein the top portion of the metal contacts has a first predetermined dimension larger than a second predetermined dimension of the low portion of the metal contacts formed within the contact openings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 illustrates a schematic isometric view of a system that may be used in conjunction with embodiments of the present invention to form multiple layers of a desired pattern.

FIG. 2 illustrates a schematic top plan view of the system in FIG. 3A according to one embodiment of the invention.

FIG. 3 illustrates a flow chart of methods to metalize a solar cell according to one embodiment of the invention.

FIGS. 4A-4D illustrate schematic cross sectional views of a solar cell during different stages in a sequence according to one embodiment of the invention.

FIG. 5 illustrates a flow chart of methods to metalize a solar cell according to another embodiment of the invention; and

FIGS. 6A-6C illustrates schematic cross sectional views of a solar cell during different stages in a sequence according to one embodiment of the invention.

For clarity, identical reference numerals have been used, where applicable, to designate identical elements that are common between figures. It is contemplated that features of one embodiment may be incorporated in other embodiments without further recitation.

### DETAILED DESCRIPTION

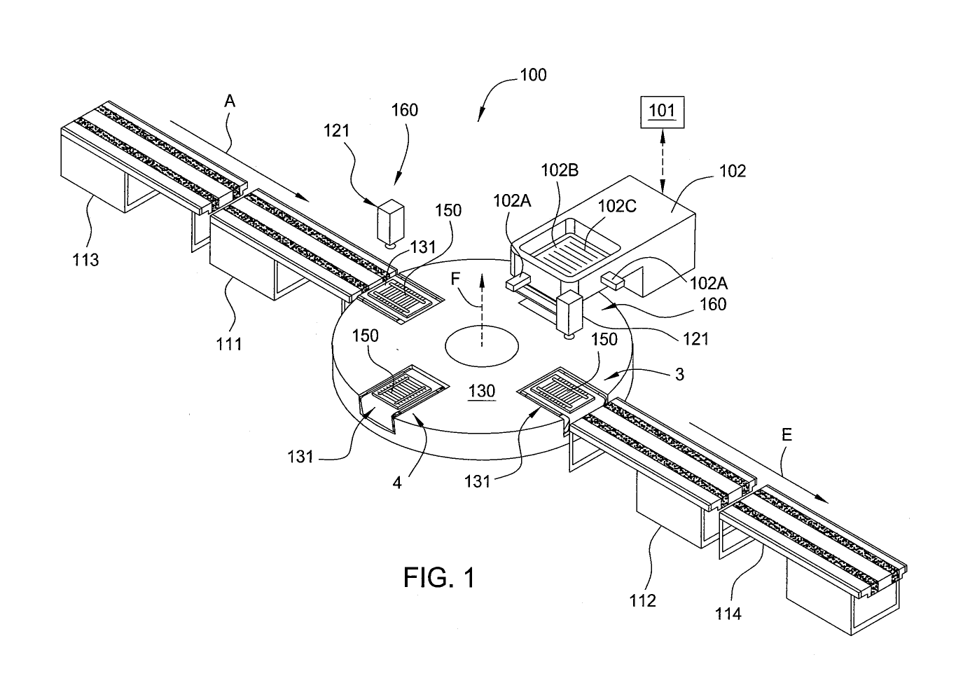

Embodiments of the invention are about the formation of a high efficiency solar cell using methods to form metal contact structures of a solar cell device. The high efficiency solar cell may be obtained by maintaining minimum contact area between the metal contacts formed onto the silicon substrate so as to achieve low contact resistivity and low recombination loss. In one embodiment, the method includes depositing a dielectric material that is used to define the active regions and/or contact structure of a solar cell device. Various techniques may be used to form the active regions and/or contact structure of the solar cell. Solar cell substrates (e.g., substrate 150 in FIGS. 1-2, 4 and 6) that may benefit from the invention include substrates that contains organic material, single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallium indium phosphide (GaInP₂), as well as heterojunction cells, such as GaInP/GaAs/Ge or ZnSe/GaAs/Ge substrates, that are used to convert sunlight to electrical power.

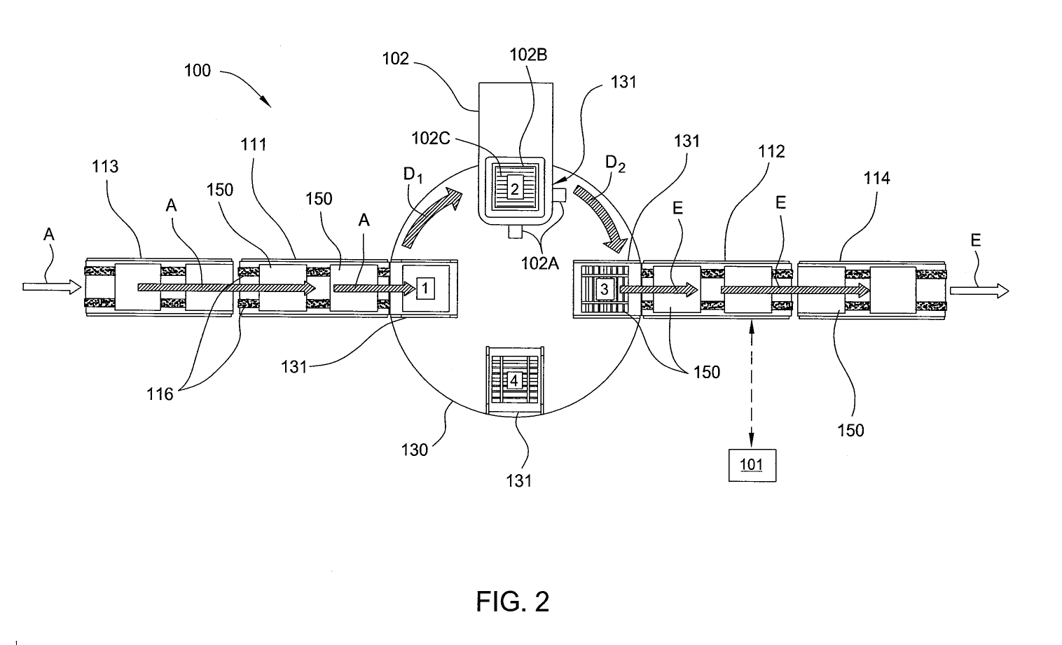

FIG. 1 is a schematic isometric view and FIG. 2 is a schematic top plan view illustrating one embodiment of a screen printing system, or system 100, that may be used in conjunction with embodiments of the present invention to form metal contacts in a desired pattern on a surface of a solar cell substrate 150. In one embodiment, the system 100 includes an incoming conveyor 111, a rotary actuator assembly 130, a screen print chamber 102, and an outgoing conveyor 112. The incoming conveyor 111 may be configured to receive the substrate 150 from an input device, such as an input conveyor 113 (i.e., path “A” in FIG. 1B), and transfer the substrate 150 to one of a plurality of printing nests 131 coupled to the rotary actuator assembly 130. The outgoing conveyor 112 may be configured to receive the processed substrate 150 from another printing nest 131 coupled to the rotary actuator assembly 130 and transfer the substrate 150 to a substrate removal device, such as an exit conveyor 114 (i.e., path “E” in FIG. 1). The input conveyor 113 and the exit conveyor 114 may be automated substrate handling devices that are part of a larger production line. For example, the input conveyor 113 and the exit conveyor 114 may be part of the Softline™ tool, of which the system 100 may be a module.

The rotary actuator assembly 130 may be rotated and angularly positioned about the “F” axis by a rotary actuator (not shown) and a system controller 101. The rotation of the rotary actuator assembly 130 selectively positions the printing nests 131 within the system 100 (e.g., paths “D₁” and “D₂” illustrated in FIG. 2). The rotary actuator assembly 130 may also have one or more supporting components to facilitate the control of the print nests 131 or other automated devices used to perform a substrate processing sequence in the system 100.

In one embodiment, the rotary actuator assembly 130 includes four printing nests 131, or substrate supports, that are each adapted to support the substrate 150 during the screen printing process performed within the screen print chamber 102. FIG. 2 schematically illustrates the position of the rotary actuator assembly 130 in which one printing nest 131 is in position “1” to receive the substrate 150 from the incoming conveyor 111, another printing nest 131 is in position “2” within the screen print chamber 102 so that another substrate 150 can receive a screen printed pattern on a surface thereof, another printing nest 131 is in position “3” for transferring the processed substrate 150 to the outgoing conveyor 112, and an empty printing nest 131 is in position “4”, which is an intermediate stage between position “1” and position “3”.

Returning back to FIG. 1, in one embodiment, the system 100 includes an inspection assembly 160 adapted to inspect the substrate 150 located on the printing nest 131 in position “1”. The inspection assembly 160 may include one or more cameras 121 positioned to inspect the incoming, or processed substrate 150, located on the printing nest 131 in position “1”. In this configuration, the inspection assembly 160 includes at least one camera 121 (e.g., CCD camera) and other electronic components capable of inspecting and communicating the inspection results to the system controller 101 used to analyze the orientation and position of the substrate 150 on the printing nest 131.

The screen print chamber 102 is adapted to deposit material in a desired pattern on the surface of the substrate 150 positioned on the printing nest 131 in position “2” during the screen printing process. In one embodiment, the screen print chamber 102 includes a plurality of actuators, for example, actuators 102A (e.g., stepper motors or servomotors) that are in communication with the system controller 101 and are used to adjust the position and/or angular orientation of a screen printing mask 102B (FIG. 2) disposed within the screen print chamber 102 with respect to the substrate 150 being printed. In one embodiment, the screen printing mask 102B is a metal sheet or plate with a plurality of features 102C (FIG. 2), such as holes, slots, or other apertures formed therethrough to define a pattern and placement of screen printed material (i.e., ink or paste) on a surface of the substrate 150. In general, the screen printed pattern that is to be deposited on the surface of the substrate 150 is aligned to the substrate 150 in an automated fashion by orienting the screen printing mask 102B in a desired position over the substrate surface using the actuators 102A and information received by the system controller 101 from the inspection assembly 160. In one embodiment, the screen print chamber 102 are adapted to deposit a metal containing or dielectric containing material on a solar cell substrate having a width between about 125 mm and 156 mm and a length between about 70 mm and 156 mm. In one embodiment, the screen print chamber 102 is adapted to deposit a metal containing paste on the surface of the substrate to form the metal contact structure on a surface of a substrate.

The system controller 101 facilitates the control and automation of the overall system 100 and may include a central processing unit (CPU) (not shown), memory (not shown), and support circuits (or I/O) (not shown). The CPU may be one of any form of computer processors that are used in industrial settings for controlling various chamber processes and hardware (e.g., conveyors, optical inspection assemblies, motors, fluid delivery hardware, etc.) and monitor the system and chamber processes (e.g., substrate position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 101 determines which tasks are performable on a substrate. The program is software readable by the system controller 101, which includes code to generate and store at least substrate positional information, the sequence of movement of the various controlled components, substrate optical inspection system information, and any combination thereof.

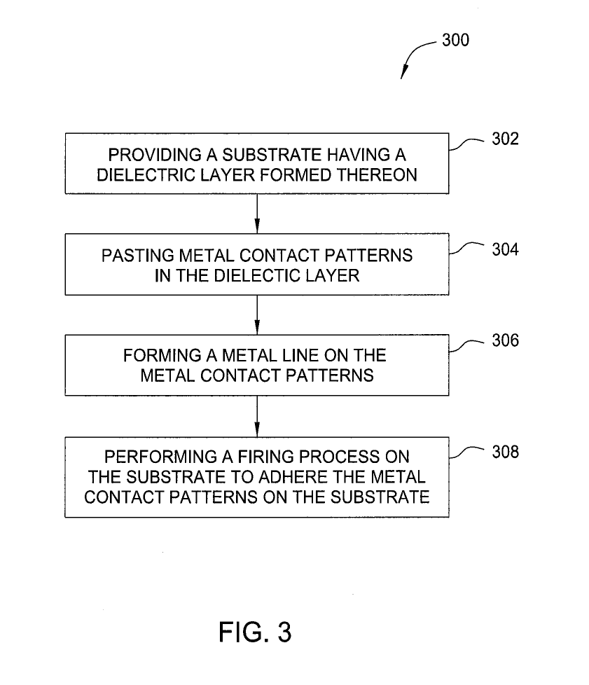

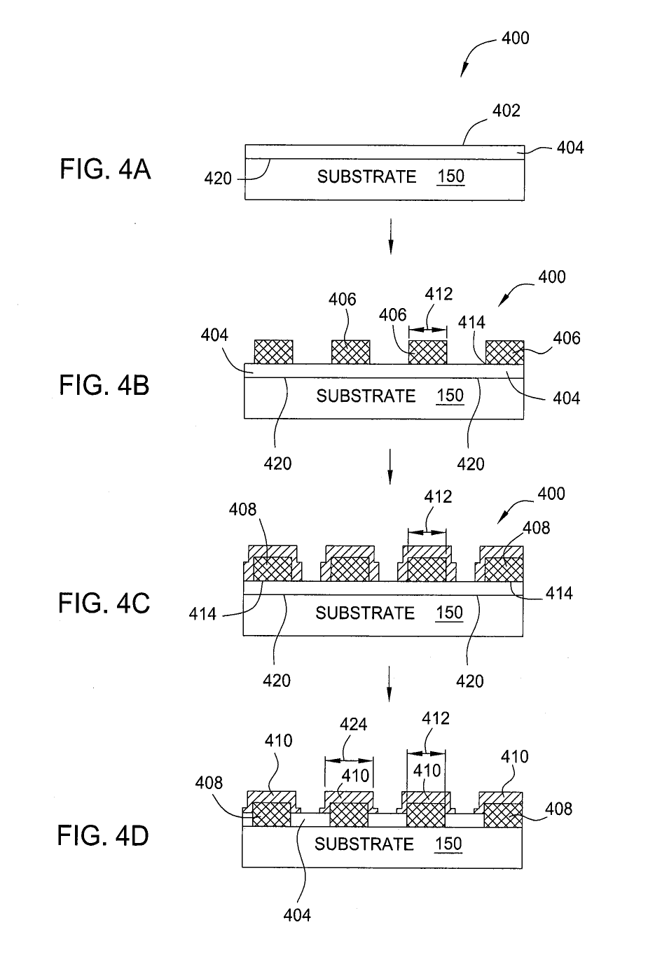

FIG. 3 illustrates a process sequence 300 used to form front contact structures on a solar cell. The sequence found in FIG. 3 corresponds to the stages depicted in FIGS. 4A-4D, which are discussed herein. FIGS. 4A-4D illustrate schematic cross sectional views of a solar cell substrate 150 during different stages in a processing sequence used to form contact structures on a surface 402 of solar cells 400.

The process sequence 300 starts at step 302 by providing a substrate, such as the substrate 150, to a screen print chamber, such as the screen print chamber 102 depicted in FIGS. 1-2. The substrate 150 may have a dielectric layer 404 formed on the substrate 150, as depicted in FIG. 4A. The substrate 150 may be a single crystal or multicrystalline silicon substrate, silicon containing substrate, doped silicon containing substrate, or other suitable substrates. In one embodiment, the substrate 150 is a doped silicon containing substrate with either p-type dopants or n-type dopants in a crystalline silicon substrate. In the embodiment depicted herein, the substrate 150 is p-type silicon that has a surface 420 of n-type dopant. The interface between the n-type and p-type regions creates an electric field that collects the photogenerated carriers from the absorption of sunlight. The n-type dopant on the surface is commonly phosphorus, although other n-type dopants may be used. The opposite polarities (i.e., n-type substrate with a thin surface region doped with a p-type dopant) could also be used.

The dielectric layer 404 disposed on the substrate 150 may be a silicon oxide layer, such as a silicon dioxide layer, a silicon nitride layer, a silicon oxynitride (SiON) layer, a composite layer including more than one dielectric layers, combination thereof, or the like, formed on the substrate 150. The dielectric layer 404 may be formed using a conventional thermal oxidation process a rapid thermal oxidation process, an atmospheric pressure or low pressure CVD process, a plasma enhanced CVD process, a PVD process, or applied using a sprayed-on, spin-on, roll-on, screen printed, or other similar type of deposition process. In one embodiment, the dielectric layer 404 is a silicon nitride layer that is between about 50 Å and about 3000 Å thick. In another embodiment, the dielectric layer 404 is a silicon nitride layer that is less than about 2000 Å thick. In one embodiment, the dielectric layer 404 is a silicon nitride layer having a thickness between about 100 Å and about 1000 Å, which is formed on the surface 420 of the doped silicon containing substrate 150. In another embodiment, the dielectric layer 404 is an aluminum oxide layer that is between about 30 Å and about 3000 Å thick. Aluminum is particularly useful for passivation of p-type as opposed to n-type surfaces. It should be noted that the discussion of the formation of a silicon nitride/silicon oxide type dielectric layer is not intended to be limiting as to the scope of the invention described herein since the dielectric layer 404 could also be formed using other conventional deposition processes (e.g., PECVD deposition) and/or be made of other dielectric materials.

In another embodiment, the dielectric layer 404 comprises a multilayer film stack, such as a silicon oxide/silicon nitride layer stack (e.g., a silicon oxide layer (e.g., layer(s) ˜20 Å to ˜3000 Å thick) and a silicon nitride layer (e.g., layer(s) ˜100 Å to ˜1000 Å thick)), an amorphous silicon/silicon oxide layer stack (e.g., amorphous silicon layer (e.g., ˜30 to 100 Å thick) and silicon oxide layer (e.g., ˜100 to 3000 Å thick)), or an amorphous silicon/silicon nitride stack (e.g., amorphous silicon layer (e.g., ˜30 to 100 Å thick) and silicon nitride layer (e.g., ˜100 to 1000 Å thick)). In one example, a 50 Å amorphous silicon layer is deposited on a silicon substrate using a CVD process, and then a 750 Å silicon nitride layer is deposited using a CVD or PVD process. In another example, a 50 Å silicon oxide layer is formed using a rapid thermal oxidation process on a silicon substrate, and then a 750 Å silicon nitride is deposited on the silicon oxide layer using a CVD or PVD process. In another example, the dielectric layer 404 comprises a multilayer film stack of aluminum oxide and silicon nitride. An example of a deposition chamber and/or process that may be adapted to form an amorphous silicon layer, silicon nitride, or silicon oxide discussed herein are further discussed in the commonly assigned and copending U.S. patent application Ser. Nos. 12/178,289, filed Jul. 23, 2008, and the commonly assigned U.S. patent application Ser. No. 12/202,213, filed Aug. 29, 2008, which are both herein incorporated by reference in their entirety.

In one embodiment, the silicon oxide or silicon nitride formation process is performed in a Vantage RadiancePlus™ RTP, Vantage RadOx™ RTP, or Applied Producer DARC®, or other similar chamber available from Applied Materials Inc. of Santa Clara, Calif. It is also contemplated that deposition equipment from other manufactures may also be utilized.

At step 304, contact metal paste 406 is selectively deposited on the dielectric layer 404 in the screen print chamber 102 to form metal contacts by use of an ink jet printing, rubber stamping, stencil printing, screen printing, or other similar process to form and define a desired pattern where electrical contacts to the underlying substrate surface (e.g., silicon) are formed, as depicted in FIG. 4B. In one embodiment, the contact metal paste 406 is disposed on the dielectric layer 404 to form the metal contacts (408, as depicted in FIG. 4C) by a screen printing process in which contact metal paste 406 is printed in the dielectric layer 404 through a stainless steel screen with a mask that has an array of features ranging in size from about 10 μm to about 1000 μm in size that are placed on around 2 mm centers. In one example, the screen printing process may be performed in a SoftLine™ available from Baccini S.p.A, which is a division of Applied Materials Inc. of Santa Clara, Calif. It is also contemplated that deposition equipment from other manufactures may also be utilized.

As the contact metal paste 406 provides metal source to form metal contacts 408 on the substrate 150 during the subsequent firing process (further discussed below with reference to FIG. 4C), the contact area where the contact metal paste 406 is in connection with the dielectric layer 404 is desired to be as small as possible to minimize recombination losses at the contact in order to maximize the voltage. The minimum size is determined by the need to minimize contact resistance losses and by the print technology. In one embodiment, the contact metal paste 406 disposed on the dielectric layer 404 is configured to have a width 412 (e.g., or a diameter) less than about 50 μm. In one example, the contact metal paste 406 may be configured to be in circular holes, slots, rectangular shaped holes, hexagonal shaped holes, or other desirable shape so as to produce the metal contacts 408 having similar shapes on the dielectric layer 404.

In one embodiment, the contact metal paste 406 includes polymer resin having metal particles disposed therein. The polymer and particle mixture is commonly known as “pastes” or “inks”. The polymer resins act as a carrier to help enable printing of the metal paste 406 onto the dielectric layer 404. Other organic chemicals are added to tune the viscosity, surface wetting, or other properties of the paste. The polymer resin and other organics are removed from the dielectric layer 404 or from the substrate 150 during the subsequent firing process. Glass frits may also be included in the contact metal paste 406. Chemicals contained in the glass frits in the contact metal paste 406 can dissolve the dielectric layer 404 disposed on the substrate 150 to allow metal to dispose (e.g., firing through) within the dielectric layer 404 to form contact areas/contact holes 414 on the surface 420 of the substrate 150, as well as facilitating coalescence of the metal particles. Glass frits thus enables the contact metal paste 406 to pattern the dielectric layer 404 leaving metal particles in the dielectric layer 404 so as to print metal contacts 408 into the dielectric layer 404.

In one embodiment, metal particles included in the contact metal paste 406 may be selected from silver, silver alloy, copper (Cu), tin (Sn), cobalt (Co), rhenium (Rh), nickel (Ni), zinc (Zn), lead (Pb), and/or aluminum (Al), or other suitable metal particles to provide proper metal source for forming the metal contacts 408 in the dielectric layer 404. The contact metal paste 406 may include silver (Ag) particles formed in polymer resin having glass frits disposed therein to form silver metal contacts 408 (in FIG. 4C) in the dielectric layer 404.

In another embodiment, the contact metal paste 406 may include an etchant material, such as ammonium fluoride (NH₄F) containing material, having metal particles disposed therein. The ammonium fluoride (NH₄F) containing material is formulated to etch the dielectric layer 404 by a subsequent firing process and be evaporated at the firing process. In one example, the contact metal paste 406 may contain 200 g/l of ammonium fluoride (NH₄F), 50 g/l of 2000 MW polyethylene glycol (PEG) and 50 g/l of ethyl alcohol with the remainder of the 1 liter volume being DI water. Metal particles may be disposed in the contact metal paste. In another example, one liter of the contact metal paste may contain 90 milliliters of a 6:1 BOE etching solution, 5 g of 500 MW polyethylene glycol (PEG) and 5 g of ethyl alcohol with the remainder of the volume being DI water with a desired amount of metal particles dispensed or disposed therein. Additional components in the contact metal paste are generally selected so as to promote effective “wetting” of the dielectric layer 404 while minimizing the amount of spreading that can affect the formed feature/contact metal patterns in the dielectric layer 404. While polyethylene oxide (i.e., polyethylene glycol) based materials and other related materials work well as a surfactant in the contact metal paste, they also decompose at temperatures over 250 degrees Celsius to form volatile byproducts thereby avoiding the need for a post-rinse step to clean the substrate surface after heating the substrate in the next step.

In one embodiment, the contact metal paste 406 comprises an etchant material, ammonium fluoride (NH₄F), having silver metal (Ag) disposed therein. Ammonium fluoride (NH₄F) a solvent that forms a homogeneous mixture with ammonium fluoride, a pH adjusting agent (e.g., BOE, HF), and a surfactant/wetting agent. In one example, the solvent is dimethylamine, diethylamine, triethylamine or ethanolamine that are disposed in an aqueous solution. In one example, the surfactant/wetting agent may be polyethylene glycol (PEG), polypropylene glycol, polyethylene glycol-polypropylene glycol-block-copolymer, or glycerin. It is believed that one benefit of using an alkaline chemistry is that no volatile HF vapors will be generated until the subsequent heating process(es) begins to drive out the ammonia (NH₃), thus reducing the need for expensive and complex ventilation and handling schemes prior to performing the heating process(es).

At step 306, a metal line 410 is formed on the metal contacts 408 to balance the overall area coverage of metal structures required to be formed in the solar cell devices 400 so as to maintain desired conductivity formed in the solar cell devices 400, as shown in FIG. 4C. The metal line 410 is formed on the metal contacts 408 by use of an ink jet printing, rubber stamping, stencil printing, screen printing, or other similar process, as described above. In this deposition process, the metal paste used to form the metal line 410 is selected to allow the metal paste (e.g., to be formed as the metal line 410) to adhere on the metal contacts 408 without damaging and/or altering the film properties of the underlying metal contacts 408 and dielectric layer 404, so called a “non-fire-through” process. In one embodiment, the metal paste is disposed on the metal contacts 408 to form the metal line 410 by a screen printing process in which metal paste is printed on the metal contacts 408 without etching through, altering, firing through the underlying metal contacts 408 and the dielectric layer 404. In one example, the screen printing process is performed in a SoftLine™ available from Baccini S.p.A, which is a division of Applied Materials Inc. of Santa Clara, Calif. It is also contemplated that screen printing equipment from other manufactures may also be utilized.

In one embodiment, the metal paste selected to be disposed on the metal contacts 408 is a metal containing metal paste configured to form the metal line 410 containing a desired metal element on the substrate 150. Suitable examples of the metal elements that may be used to form the metal paste include copper (Cu), silver (Ag), tin (Sn), cobalt (Co), rhenium (Rh), nickel (Ni), zinc (Zn), lead (Pb), and/or aluminum (Al). In one embodiment depicted here, silver (Ag) or copper (Cu) is used as the metal source material to form the metal paste. After the metal paste is disposed, printed, or pasted on the metal contacts 408, a “non-fire-through” firing process is performed to assist melting the metal paste, thereby leaving the silver metal adhering on the metal contacts 408 without damaging the dielectric layer 404. In one embodiment, the “non-fire-through” firing process is performed a temperature within a range between about 600 degrees Celsius and about 900 degrees Celsius for a time period between about 8 second and about 12 seconds. Additionally, the “non-fire-through” firing process may also assist forming a good electrical contact among the dielectric layer 404 and the metal contacts 408.

In another embodiment, the metal line 410 may also be formed by a CVD process, a PVD process, a sputter process, a plating process, or any suitable processes. An etching process or material removal process, such as laser ablation, patterning, dry/wet etching, or other similar techniques is then followed to form desired patterns or metal grid on the metal line 410.

In one embodiment, the metal line 410 may have a width 424 of between about 50 μm and about 1000 μm so as to compensate the area coverage reduced from width 412 of the metal contacts 408 formed in the dielectric layer 404. In another embodiment, the metal line 410 may be configured to have a cross sectional area between about 10 percent and about 200 percent, such as between about 100 percent and about 200 percent, greater than the cross sectional area of the metal contacts 408 formed in the dielectric layer 404. It is noted that the term “cross sectional area” described herein generally refers to a plane parallel to the surface 420 of the substrate 150. In another embodiment, the width 424 of the metal line 410 may be configured to be between about 10 percent and about 200 percent, such as between about 100 percent and about 200 percent, wider than the width of the metal contacts 408 formed thereunder. In one embodiment, the width 424 of the metal line 410 is between about 10 μm and about 200 μm wider than the width 412 of the metal contacts 408.

At step 308, a thermal process, such as a firing and/or a sintering process, is performed on the substrate 150 to form metal contacts 408 in the dielectric layer 404 using a “fire-through” metallization process, as shown in FIG. 4D. The dielectric layer 404 is etched through during firing process, e.g., the “fire-through” metallization process, by the contact metal paste 406 to form the features/contact holes 414 in the dielectric layer 404 while allowing the metal contacts 408 to be disposed in the features/contact holes 414 and in direct contact with the substrate 150 during the firing process. The firing process assists adhering or sintering the metal contacts 408 in the dielectric layer 404 in one step without additional etching or metal deposition process. The firing and/or sintering process may also assist evaporating the polymer or etchant material in the contact metal paste 406 from the dielectric layer 404, leaving a clean surface for the metal contact 408 to be disposed therein. The firing/sintering process is used to densify the contact metal paste 406 while removing etchants or polymer disposed in the contact metal paste 406. The firing process creates an ohmic contact between the metal contacts 408 and the surface 420 of the substrate 150. In one embodiment, the peak firing temperature may be controlled between about 600 degrees Celsius and about 900 degrees Celsius, such as about 800 degrees Celsius for short time period, such as between about 8 seconds and about 12 seconds, for example, about 10 seconds.

In another embodiment, the metal contacts 408 may be formed by a drop-in replacement process, double print process, or other suitable process to place silver metals into the contact holes/features 414 to form the desired metal contacts 408 as needed.

As discussed above, as the metal contacts 408 formed in the dielectric layer 404 may create ohmic contact at the surface 420 of the substrate 150, accordingly, the dimension of the features/contact holes 414 for the metal contacts 408 to be disposed therein is controlled to be formed as small as possible to reduce contact resistivity. However, small dimension of the metal contact 408 may affect the conductivity and/or the area coverage (also cross sectional area) of the metal contacts 408 as required to be formed in the solar cell devices 400, thereby adversely reducing the overall electric performance or conversion efficiency of the solar cell devices 400 formed on the substrate 150.

It is noted that the sequence of performing the step 306 and 308 may be switched, cycled, repeated or in any order until desired thickness, profile, structures are formed on the substrate.

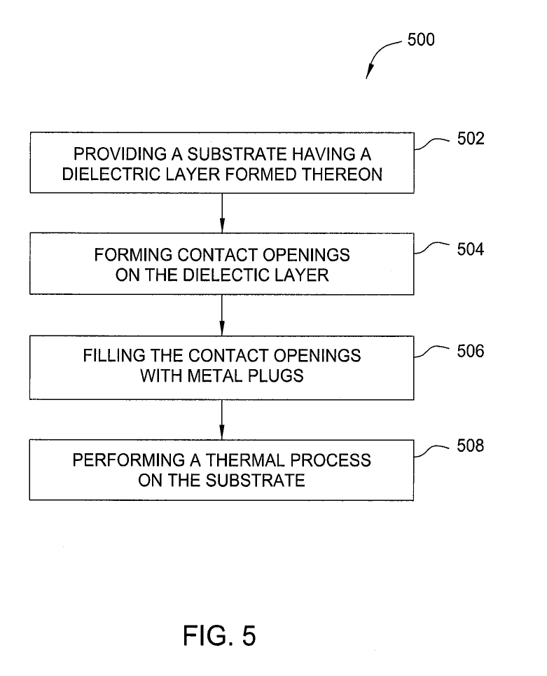

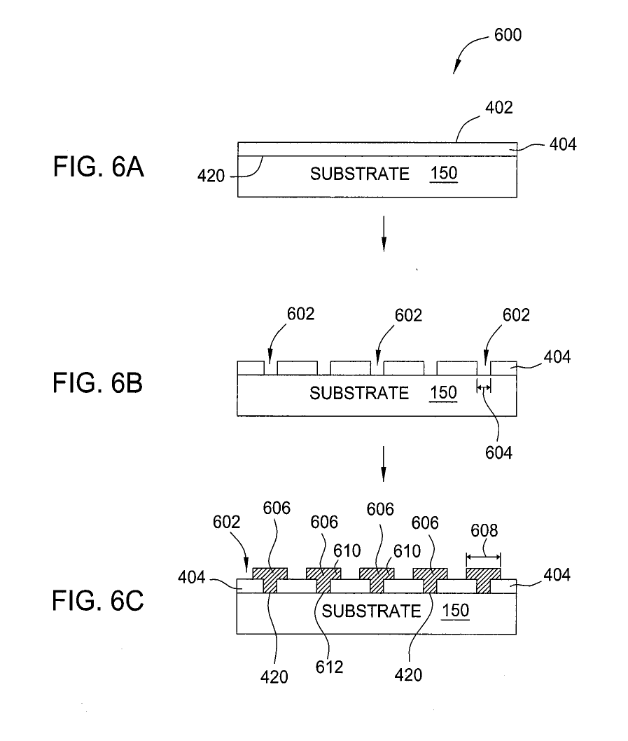

FIG. 5 illustrates a process sequence 500 used to form front contact structures on a solar cell according to another embodiment of the present invention. The sequence found in FIG. 5 corresponds to the stages depicted in FIGS. 6A-6C, which are discussed herein. FIGS. 6A-6C illustrate schematic cross sectional views of the solar cell substrate 150 during different stages in the processing sequence 500 used to form metal contact structures on a surface 402 of solar cell devices 600.

The process sequence 500 starts at step 502 by providing a substrate, such as the substrate 150 having a dielectric layer 404 disposed thereon, as depicted in FIG. 6A. The substrate is also provided with a thin layer doped to a conductivity type opposite to the doping conductivity type of the substrate. Similar to the solar cell devices 400 depicted with reference to FIGS. 4A-4D, the substrate 150 may have the dielectric layer 404 formed on the substrate 150. The substrate 150 may be a single or multicrystalline silicon substrate, silicon containing substrate, doped silicon containing substrate, or other suitable substrates. In one embodiment, the substrate 150 is a doped silicon containing substrate with either p-type dopants or n-type dopants in a crystalline silicon substrate. In the embodiment depicted herein, the substrate 150 is a p-type doped crystalline silicon substrate having boron dopants doped therein. The dielectric layer 404 may be similar to the dielectric layer 404 depicted with reference to FIGS. 4A-4D discussed above.

At step 504, a contact opening process is performed on the substrate 150 to form contact holes 602 in the dielectric layer 404, as depicted in FIG. 6B. Instead of the “fire-through” process described at step 304 in the process sequence 300 depicted with reference to FIGS. 4B-4C, the process sequence 500 described here uses two separate steps, such as the step 504 and 506, to form contact openings at a first step 504 and followed with a metal filling process at step 506 individually. By doing two separate processes, a low manufacture cost may be obtained as the contact holes 602 formed in the dielectric layer 404 may be formed in any suitable conventional material removal process, including dry/wet etching process, laser ablation process, screen printing process or any suitable process. Therefore, special “fire-through” contact metal paste, a relatively expensive complex material, does not have to be used to simultaneously form contact holes and fill metal contacts in a dielectric layer in one step.

In one embodiment, the contact holes 602 are formed in the dielectric layer 404 by an etching process. The etching process may be performed by a conventional etching process utilizing a mask layer during the etching process to form the contact holes 602 with desired patterns, features, dimensions, shapes, or configurations in the dielectric layer 404. In one embodiment, the etching process utilized to form the contact hole 602 is a dry plasma etching process utilizing a halogen containing gas, such as SF₆, as the active etchants to etch the dielectric layer 404.

In another embodiment, the contact holes 602 are formed by an etchant material selectively pasted on the dielectric layer 404 to form contact holes 602 therein. The etchant material may include an etching solution to be selectively pasted on the dielectric layer 404 by use of a conventional ink jet printing, rubber stamping, screen printing, or other similar process to form and define the contact holes 602. The etching solution as used here may be similar or the same as the solution discussed above utilized to etch the dielectric layer 404 at step 304. In one embodiment, the etchant material is disposed on the dielectric layer 404 by a screen printing process performed in a screen printing tool, such as the tool depicted in FIGS. 1-2. The etchant material is printed in the dielectric layer 404 through a polyester screen with mask that has an array of features ranging in size from about 10 μm to about 1000 μm in size that are placed on around 2 mm centers. In one example, the screen printing process is performed in a SoftLine™ available from Baccini S.p.A, which is a division of Applied Materials Inc. of Santa Clara, Calif. It is also contemplated that deposition equipment from other manufactures may also be utilized.

As discussed above, dimension of the contact holes 602 formed in the dielectric layer 404 is desired to be small so as to maintain a minimum contact resistivity. Accordingly, contact holes 602 formed in the dielectric layer 404 is controlled having a mean diameter or width 604 less than about 50 μm. In one example, the features the contact holes 602 are circular holes, slots, rectangular shaped holes, hexagonal shaped holes, or other desirable shape.

At step 506, after the contact holes 602 are formed in the dielectric layer 404, contact metal paste is selectively disposed in the dielectric layer 404, filling the contact holes 602 formed in the dielectric layer 404, as shown in FIG. 6C. The contact metal paste disposed in the contact holes 602 forms metal contacts 606 in connection with the underlying substrate 150. The contact metal paste may be disposed in the dielectric layer 404 by use of an ink jet printing, rubber stamping, stencil printing, screen printing, or other similar process to form and define a desired pattern where electrical contacts to the underlying substrate surface (e.g., silicon) are formed, as depicted in FIG. 6C. In one embodiment, the contact metal paste is disposed on the dielectric layer 404 to form the metal contacts 606 by a screen printing process in which contact metal paste is printed in the dielectric layer 404 through a polyester or stainless steel screen with mask that has an array of features ranging in size from about 10 μm to about 1000 μm in mean diameter or width that are placed on less than 2 mm centers. In one example, the screen printing process is performed in a SoftLine™ available from Baccini S.p.A, which is a division of Applied Materials Inc. of Santa Clara, Calif. It is also contemplated that screen printing tools from other manufactures may also be utilized

In one embodiment, the contact metal paste includes polymer resin to act as a carrier to help enable printing of the metal contact 606 into the dielectric layer 404. The polymer resin, such as ethylcellulose, and various chemicals, and other organics are removed from the contact areas/contact holes 414 during the subsequent thermal process. The firing process creates an ohmic contact between the metal contacts 408 and the surface 420 of the substrate 150.

In one embodiment, the contact metal paste may include metal particles disposed therein to provide proper metal source for filling the metal contacts 606 in the contact holes 602 formed in the dielectric layer 404. In one embodiment, metal particles included in the contact metal paste may be selected from silver, silver alloy, copper (Cu), tin (Sn), cobalt (Co), rhenium (Rh), nickel (Ni), zinc (Zn), lead (Pb), and/or aluminum (Al), or other suitable metal particles to provide proper metal source for forming the metal contacts 606 in the dielectric layer 404. The contact metal paste may include silver (Ag) particles formed therein to form silver metal contacts 606 in the dielectric layer 404.

As discussed above, as the metal contacts 606 formed in the dielectric layer 404 may create ohmic contact at the surface 420 of the substrate 150, accordingly, the width 604 of the contact holes 602 are small to reduce contact recombination losses. However, small dimension of the metal contacts 606 formed in the contact holes 602 may affect the conductivity and/or the area coverage (also cross sectional area) of the metal contacts 606 as required to be formed in the solar cell devices 600, thereby adversely reducing the overall electric performance of the solar cell devices 600 formed on the substrate 150. Accordingly, the metal contacts 606 formed in the contact holes 602 are configured to have a top portion 610 having a larger (i.e. wider) width 608 than a width 604 (e.g., or a cross sectional area of the top portion 610 larger than a cross sectional area of the metal contacts 606) formed in a lower portion 612 of the metal contacts 606 filling in the contact holes 602. The wider width 608 of the top portion 610 of the metal contacts 606 may assist balancing the overall area coverage of metal structures required to form in the solar cell devices 600 so as to maintain desired conductivity formed in the solar cell devices 600. In one embodiment, the top portion 610 of the metal contacts 606 may have a mean diameter or width 608 of between about 50 μm and about 1000 μm so as to compensate the area coverage reduced from width 608 of the lower portion 612 of the metal contacts 606 formed in the dielectric layer 404. In another embodiment, the width 608 of the top portion 610 of the metal contacts 606 may be configured to be between about 10 percent and about 200 percent wider than the width 604 of the lower portion 612 of the metal contacts 606 formed thereunder. In one embodiment, the width 608 of the top portion 610 of the metal contacts 606 are between about 10 μm and about 100 μm wider than the width 604 of the lower portion 612 of the metal contacts 606. In another embodiment, the top portion 610 may be configured to have a cross sectional area between about 10 percent and about 200 percent, such as between about 100 percent and about 200 percent, greater than the cross sectional area of the lower portion 612 formed in the dielectric layer 404. It is noted that the term “width” is a mean diameter of the structures (holes, vias, trenches, openings, conductive lines and the like) formed on the substrate and is used to determine a cross sectional area of the structures. It is noted that the term “cross sectional area” as utilized herein refers to the sectional area taken in a plane parallel to the surface 420 of the substrate 150.

At step 508, after the metal contacts 606 are filled in the contact holes 602 in the dielectric layer 404, a thermal annealing process (e.g., a firing process) may be performed to assist densifying, melting and adhering the metal source from the contact metal paste onto the substrate 150. The thermal annealing process as performed in this step is a so called “non-fire through” process so that the metal contacts 606 disposed in the dielectric layer 404 is thermally proceeded to be melt and adhered on the substrate surface 420 without damaging or etching through the dielectric layer 404. The thermal annealing process or the firing process may also assist evaporating the polymer or organic material in the contact metal paste from the dielectric layer 404, leaving a clean surface of the metal contacts 606 to be disposed in the dielectric layer 404. In one embodiment, the thermal annealing/firing temperature may be controlled between about 600 degrees Celsius and about 900 degrees Celsius, such as about 800 degrees Celsius for short time period, such as between about 8 seconds and about 12 seconds, for example, about 10 seconds.

While the foregoing is directed to embodiments of the present invention, other and further embodiments of the invention may be devised without departing from the basic scope thereof, and the scope thereof is determined by the claims that follow.

What is claimed is:

1. A solar cell device, comprising:
a substrate comprising a doped semiconductor material;
a surface formed on the substrate having a second doped semiconductor layer having a conductivity type opposite to the first doped semiconductor material;
a dielectric layer disposed on the surface of the substrate;
a metal contact structure formed in the dielectric layer with a first predetermined cross sectional area; and
a metal line formed on the metal contact structure with a second predetermined cross sectional area, wherein the second predetermined cross sectional area is larger than the first predetermined cross sectional area.

2. The solar cell device of claim 1, wherein the second predetermined cross sectional area of the metal line is configured to be between about 10 percent and about 200 percent greater than the first predetermined cross sectional area of the metal contact structure.

3. The solar cell device of claim 1, wherein the metal contact structure and the metal line are fabricated from at least one of silver, silver alloy, copper (Cu), tin (Sn), cobalt (Co), rhenium (Rh), nickel (Ni), zinc (Zn), lead (Pb), or aluminum (Al).

4. The solar cell device of claim 1, wherein the metal contact structure is fabricated by Ag and the metal line is fabricated by Ag or Cu.

5. The solar cell device of claim 1, wherein the dielectric layer is fabricated from a dielectric material selected from at least one of silicon oxide, silicon nitride, silicon oxynitride, aluminum oxide, or combination thereof.

6. The solar cell device of claim 1, wherein the substrate is a p-type doped silicon containing material.

7. A method for manufacturing metal contact structures for a solar cell device, comprising:
providing a substrate having a dielectric layer disposed thereon;
selectively disposing contact metal paste on the dielectric layer;
firing the contact metal paste disposed on the dielectric layer to etch through the dielectric layer, forming contact openings in the dielectric layer;
forming metal contact structures in the contact opening formed in the dielectric layer etched through the contact metal paste during the firing process; and
selectively disposing a metal line over the contact structures formed in the dielectric layer.

8. The method of claim 7, wherein the contact metal paste has a first predetermined cross sectional area utilized to form the metal contact structures in the dielectric layer with the first predetermined cross sectional area.

9. The method of claim 8, wherein the metal line formed over the metal contact structures has a second predetermined cross sectional area, wherein the second predetermined cross sectional area is configured to be larger than the first predetermined cross sectional area.

10. The method of claim 8, wherein the metal line formed over the metal contact structures has a second predetermined cross sectional area and the second predetermined cross sectional area of the metal line is configured to be between about 10 percent and about 200 percent greater than the first predetermined cross sectional area of the metal contact structure.

11. The method of claim 7, wherein the contact metal paste includes at least metal elements and glass frits disposed therein.

12. The method of claim 11, wherein the glass frit disposed in the contact metal paste etches through the dielectric layer during the firing process.

13. The method of claim 7, wherein the contact metal paste includes metal elements selected from at least one of silver, silver alloy, copper (Cu), tin (Sn), cobalt (Co), rhenium (Rh), nickel (Ni), zinc (Zn), lead (Pb), or aluminum (Al).

14. The method of claim 7, wherein the metal line and metal contact structures are fabricated by Ag.

15. The method of claim 7, wherein the firing the contact structures further comprises:
thermally annealing the substrate to a temperature between about 600 degrees Celsius and about 900 degrees Celsius.

16. A method for manufacturing metal contact structures for a solar cell device, comprising:
providing a substrate having a dielectric layer disposed thereon;
performing a contact opening process in the dielectric layer to selectively form a plurality of contact openings in the dielectric layer;
disposing metal contacts in the contact openings formed in the dielectric layer, wherein the metal contacts include a top portion connecting to a low portion, wherein the top portion of the metal contacts has a first predetermined cross sectional area larger than a second predetermined cross sectional area of the low portion of the metal contacts formed within the contact openings.

17. The method of claim 16, wherein the first predetermined cross sectional area is configured to be between about 10 percent and about 200 percent greater than the second predetermined cross sectional area.

18. The method of claim 16, wherein the performing a contact opening process further comprises:
performing an etching process in the dielectric layer to form the plurality of contact openings.

19. The method of claim 16, wherein the metal contacts are selected from at least one of silver, silver alloy, copper (Cu), tin (Sn), cobalt (Co), rhenium (Rh), nickel (Ni), zinc (Zn), lead (Pb), or aluminum (Al).

20. The method of claim 16, further comprising:
performing a firing process on the substrate.
